(19) United States
(12) Patent Application Publication
(10) Pub. No.: US 2024/0339971 A1
(43) Pub. Date: Oct. 10, 2024

(54) ELECTRICAL CIRCUIT FOR LOAD LINE MODULATION OF LINEAR POWER AMPLIFIERS

(71) Applicant: Thomas Meier, Starnberg (DE)

(72) Inventor: Thomas Meier, Starnberg (DE)

(21) Appl. No.: 18/294,077

(22) PCT Filed: Aug. 2, 2022
(86) PCT No.: PCT/EP2022/071665

§ 371 Date: Jan. 31, 2024

(30) Foreign Application Priority Data
Aug. 3, 2021 (DE) 10 2021 120 119.5

(51) Int. Cl. H03F 3/24

(52) U.S. Cl. CPC H03F 3/245; H03F 2200/451

(57) ABSTRACT

The invention relates to a circuit (1) for transmitting and amplifying an analog useful signal (2) in a communication device, comprising a signal transmission path (25) via which the useful signal (2) is transmitted in modulated form, a power amplifier (5) arranged in the signal transmission path (25) and having an input (4) and an output (6) which serves to amplify the useful signal (2), a load modulation circuit (7) connected to the output (6) of the power amplifier (5) and having a first and a second controllable capacitor (8, 9), the first controllable capacitor (8) being controlled by a control signal (40) corresponding to the useful signal (2), and the second controllable capacitor (9) being controlled by a control signal (41) corresponding to the inverted useful signal (2), the change in capacitance or amplitude of the capacitance modulation changing in accordance with the inverted useful signal (2). amplitude of the capacitance modulation of capacitor (8) to the capacitance change or amplitude of the capacitance modulation of capacitor (9) behaves like the ratio of output to input impedance of the load modulation circuit (7).

The invention relates to an electrical circuit for load line modulation of linear power amplifiers.

### BACKGROUND OF THE INVENTION

Electrical circuits, which are referred to below, are used, for example, in the field of mobile telecommunications to transmit an analog useful signal from a transmitter to a receiver in a communication network. The communication network can, for example, comprise a large number of mobile devices, such as cell phones or tablet computers. The useful signal is typically a high-frequency, modulated signal that contains information, for example, voice or image information. A simple useful signal is, for example, an audio signal that is picked up by a microphone, processed by an electrical circuit and finally transmitted by an antenna via radio.

Circuits known from the state of the art comprise a signal transmission path via which the useful signal is transmitted in modulated form to the output of the circuit (an antenna), whereby a power amplifier is arranged in the signal transmission path which amplifies the modulated useful signal. In order to keep the electrical power loss of the power amplifier as low as possible, there are various methods, which are briefly described below.

FIG. 1a shows a circuit 1 known from the prior art for amplifying an analog useful signal 2 in a communication device, with a signal transmission path 25 on which an amplitude-modulated signal 3 is routed. The actual useful signal 2 is contained in the envelope of the amplitude-modulated signal 3.

A linear power amplifier 5 connected in the signal transmission path 25 amplifies the phase- and amplitude-modulated signal 3. The maximum signal level of the modulated signal 3 at the input of the power amplifier 5 is 1 V, for example. At the output of the power amplifier 5, the maximum signal level is 20 V, for example. The power amplifier 5 is connected with its supply input 31 to a fixed supply voltage Vcc.

FIG. 1b shows the signal curve of the amplified, modulated signal 3 and a constant supply voltage Vcc. The shaded area 35 marks the power loss resulting from the amplification. The latter is roughly proportional to the difference between the supply voltage Vcc and the signal level. Consequently, the power loss is high at a low signal level and rather low at a high signal level. Because the power amplifier is supplied with a constant supply voltage Vcc, there is a relatively high power loss over time. The power amplifier 5 therefore has a correspondingly low efficiency, whereby the term “efficiency” refers to the ratio of the output power to the supply power of the power amplifier 5.

FIG. 2a shows another circuit 1 known from the prior art for amplifying an analog useful signal in a communication device, which operates according to the principle of “envelope tracking”. The circuit 1 in turn has a signal transmission path 25 on which an amplitude-modulated useful signal 3 is guided in the direction of an antenna (not shown). A linear power amplifier 5 arranged in the signal transmission path 25 amplifies the modulated signal 3 to a higher signal level. In contrast to the circuit in FIG. 1, however, the power amplifier 5 is not supplied by a fixed supply voltage, but by a variable supply voltage that follows the signal level of the modulated useful signal 3.

For this purpose, the circuit 1 comprises an envelope detector 32, which determines the signal level of the modulated signal 3 and controls a DC/DC converter 33, which supplies the power amplifier 5 with a variable supply voltage. At lower signal levels, the DC/DC converter 33 generates a lower supply voltage Vcc and at higher signal levels a higher supply voltage Vcc. As the peak value determination using the envelope detector 32 and the adaptation of the supply voltage Vcc to the signal level requires a certain amount of time, a delay element 34 is connected before the input of the power amplifier 5.

FIG. 2b shows the time characteristic of the amplified amplitude-modulated signal 3 and the supply voltage 36 applied to the supply input 31 of the power amplifier 5. As can be seen, the supply voltage 36 follows the signal level of the amplitude-modulated signal 3 at a small distance. The losses generated by the power amplifier 5 are therefore relatively low and the efficiency of the amplifier is comparatively high.

FIG. 3a shows another circuit known from the prior art for amplifying an analog useful signal 2, which operates according to the principle of loadline modulation. The circuit 1 in turn comprises a power amplifier 5 connected in the signal transmission path 25, which linearly amplifies an amplitude-modulated useful signal 3. The power amplifier 5 is supplied by a fixed supply voltage Vcc. In contrast to the circuit in FIG. 2a, however, it is not the supply voltage Vcc of the power amplifier 5 that is modulated here, but the electrical load prevailing at the output of the power amplifier 5. For this purpose, the circuit 1 comprises an envelope detector 32, which determines the signal level of the modulated signal 3 and controls various controllable capacitors 8, 9 (also: varactors) as a function thereof. As a result, the load prevailing at the output of the power amplifier 5 or its impedance changes depending on the signal level of the amplitude-modulated signal 3.

FIG. 3b shows the curve of the collector current I_{C} of a transistor contained in the power amplifier 5 over the collector-emitter voltage U_{CE} of the transistor at different control voltages as well as a load characteristic 37 of a specific electrical load present at the output of the power amplifier 5. As can be seen, the load characteristic curve changes depending on the impedance of the output load. With full control, a larger range of I_{C} is then used at a specific, fixed collector-emitter voltage U_{CE} and a steeper load characteristic and the higher average current is then set at operating point B2. With a flatter load characteristic, an operating point B1 is set accordingly. The collector current I_{C} of the transistor thus varies depending on the load or the level of the modulated useful signal 3. Accordingly, the output power of the amplifier 5 also varies depending on the level of the modulated useful signal 3. Circuits that operate according to the principle of “loadline modulation” are known, for example, from U.S. Pat. No. 7,202,734 B1 or 10,122,326 B2. However, one disadvantage of the known circuits is that the useful signal is disturbed by the modulation of the load.

FIGS. 4a and 4b show another method and circuit known from U.S. Pat. No. 7,911,277 B2 for the adaptive adjustment of power amplifiers. Using the method described there, mismatches of both the real part and the imaginary part of the load can be corrected by changing two varactors. In an iterative process, both varactors are increased by the same value if the mismatch of the imaginary part is measured with detectors and then one varactor is increased by a certain value and the second varactor is decreased by the same value if the mismatch of the real part is present. These two adjustment steps are iterated until a perfect adjustment is achieved, i.e. any mismatch is eliminated. A mismatch of the real part is generated at each iteration step for the imaginary part adjustment (upper part of the flow diagram in FIG. 4a), which becomes smaller and smaller with increasing iteration. Similarly, in the loop for real part adjustment, a mismatch of the imaginary part is generated, which becomes smaller and smaller with increasing iteration. FIG. 5 shows an example of the course of the adaptation over the iterations run through, starting with the mismatch at point P1 with the iterations according to the flow diagram in FIG. 4a up to the perfect adaptation at point P7. The main objective of U.S. Pat. No. 7,911,277 B2 is therefore to detect and eliminate a mismatch. An application in the context of a system modulating the useful signal is not described there and would generate considerable signal distortions due to the mismatches occurring in the iteration.

### TASK OF THE INVENTION

It is therefore a task of the present invention to create a circuit for amplifying an analog useful signal which operates efficiently even at high modulation bandwidths and causes little interference to the useful signal. With the principle of load line modulation of power amplifiers that is used, it is particularly important to
minimize or eliminate the amplitude and phase deviation of the useful signal (AM/AM conversion and AM/PM conversion) by means of load line modulation
suppress the intermodulation products that inevitably arise during the modulation of the varactor diodes used for load impedance modulation

This task is solved in accordance with the invention by the features given in patent claim 1. Further embodiments of the invention are shown in the sub-claims.

According to the invention, a communication device with a circuit for transmitting and amplifying an analog useful signal is proposed, comprising:
a signal transmission path via which the useful signal is transmitted in modulated form,
a power amplifier arranged in the signal transmission path with an input and an output that is used to amplify the useful signal,
a load modulation circuit connected to the output of the power amplifier, comprising a first and a second controllable capacitor both connected to the signal transmission path and connected to a reference potential, an inductor being arranged in the signal transmission path between the two controllable capacitors; and
a control circuit which controls the two controllable capacitors in antiphase and depending on the useful signal in such a way that the ratio of the capacitance change of the first controllable capacitor to the capacitance change of the second controllable capacitor corresponds to the ratio of the output impedance to the input impedance of the load modulation circuit.

According to a first embodiment of the invention, the control circuit generates identical, but antiphase control signals for the two controllable capacitors. In this case, the controllable capacitors or varactors must be selected in such a way that the above-mentioned condition is still met if the control signals change by the same amount, namely that the ratio of the capacitance change of the first controllable capacitor to the capacitance change of the second controllable capacitor corresponds to the ratio of the output impedance to the input impedance of the load modulation circuit. For this purpose, for example, two identical varactors with identical capacitance characteristics can be used, whereby the two varactors are brought into different areas of the characteristic curve with different slopes during control. If necessary, one of the two varactors is supplemented by an additional capacitor in order to increase or decrease the capacitance and thus fulfill the above-mentioned condition. In this case, one of the controllable capacitors comprises a varactor and an additional capacitor, for example, and the other controllable capacitor comprises the same varactor. The term “controllable capacitor” is therefore to be understood as a unit that can comprise at least one varactor and possibly one or more additional capacitors.

According to another embodiment, two different controllable capacitors with different capacitance characteristics (with different slopes) can be used. In this case, however, the control signals for the two controllable capacitors must be different (and also in phase opposition) in order to fulfill the above-mentioned condition. With knowledge of the capacitance characteristics of the controllable capacitors and the control range of the control signals, the skilled person can easily set up the control circuit so that the above condition is met.

According to one embodiment of the invention, a controllable inductor is connected to the output of the power amplifier, followed by the aforementioned load modulation circuit, which generates the load line modulation with the aid of controllable capacitors.

The controllable inductance is preferably controlled by the control circuit in such a way that the inductance value of the controllable inductance corresponds to the product of the inductance value of the inductance arranged between the two controllable capacitors multiplied by the ratio of the capacitance value of the second controllable capacitor to the capacitance value of the first controllable capacitor.

The control circuit for controlling the controllable capacitors preferably generates a control signal corresponding to the useful signal and a control signal corresponding to the inverted useful signal. One of the control signals is preferably applied to a terminal (e.g. anode or cathode) of the first controllable capacitor and the second, inverted control signal is applied to the same terminal (e.g. anode or cathode) of the second controllable capacitor.

The control circuit according to the first embodiment preferably comprises a non-inverting operational amplifier whose output is connected to a terminal of the first controllable capacitor, and an inverting operational amplifier whose output is connected to a terminal of the second controllable capacitor. As a result, the two controllable capacitors are controlled in antiphase.

According to a first variant, the input of the non-inverting operational amplifier and the input of the inverting operational amplifier are connected to the signal transmission path via at least one envelope detector circuit. The envelope detector circuit is preferably used to generate a control signal from the modulated useful signal derived from the signal transmission path.

According to another variant, the input of the non-inverting operational amplifier and the input of the inverting operational amplifier are connected to a baseband circuit that provides the useful signal in its natural spectrum (the baseband). The baseband circuit can, for example, be a baseband chip such as is integrated in most conventional mobile communication devices. The baseband signal generated by the baseband chip can be fed directly to the two operational amplifiers as an input signal or control signal, which is amplified by the operational amplifiers and then used to control the two controllable capacitors.

In a first embodiment, the load modulation circuit contains at least two controllable capacitors (also: varactors). Preferably, both the first and the second controllable capacitor are connected to the signal transmission path and connected to a reference potential, in particular ground, with an inductance being arranged in the signal transmission path between the two controllable capacitors.

The control circuit according to a particular embodiment of the invention preferably comprises an operational amplifier, the output of which is connected to both the first and the second controllable capacitor and which provides at its output a control signal corresponding to the non-inverted or inverted useful signal for both controllable capacitors. One of the two controllable capacitors is connected to a negative reference potential, e.g. earth, while the other is connected to a positive reference potential, so that an increase in the voltage of the useful signal results in an increase in the capacitance of one capacitor and a decrease in the capacitance of the other, thus restoring the phase opposition of the capacitance changes.

A choke is preferably connected in at least one signal path via which the control signal generated by the operational amplifier is transmitted to one of the controllable capacitors.

Also in the control circuit according to the second embodiment (which has only one operational amplifier generating a single control signal), the useful signal supplied to the operational amplifier at its input can either be derived from the signal transmission path or obtained from a baseband circuit.

### BRIEF DESCRIPTION OF THE DRAWINGS

The invention is explained in more detail below with reference to the attached drawing. It shows:

FIG. 1a is a schematic diagram of an amplifier circuit known from the prior art with a power amplifier supplied with a constant supply voltage;

FIG. 1b shows the signal curve of a modulated useful signal output by the power amplifier of FIG. 1a and the supply voltage applied to the power amplifier;

FIG. 2a is a schematic circuit diagram of an amplifier circuit known from the prior art, which operates according to the principle of “envelope tracking”;

FIG. 2b shows the signal curve of a modulated useful signal output by the power amplifier of FIG. 2a in relation to the supply voltage applied to the power amplifier;

FIG. 3a is a schematic circuit diagram of an amplifier circuit known from the prior art, which operates according to the principle of “load line modulation”;

FIG. 3b Various load curve characteristics as a function of the electrical load present at the output of the power amplifier of the circuit in FIG. 3a;

FIG. 4a the flow chart from the prior art load adjustment method of U.S. Pat. No. 7,911,277 B2;

FIG. 4b a matching circuit proposed in the prior art U.S. Pat. No. 7,911,277 B2;

FIG. 5 shows the exemplary locus curve of the input impedance of the load modulation circuit after application of the principle proposed in U.S. Pat. No. 7,911,277 B2;

FIG. 6 shows the basic load modulation circuit with two varactors to ground and a series inductance;

FIG. 7 the locus curve of the input impedance of the load modulation circuit from FIG. 6 for different terminating resistors Rout

FIG. 8 shows the phase progression of S21 of the load modulation circuit from FIG. 6 for different terminating resistors Rout;

FIG. 9 The load modulation circuit from FIG. 6 extended by the controllable inductance (50);

FIG. 10a shows the phase response of S21 of the load modulation circuits in FIGS. 6 and 9 for Rout=50 Ohm;

FIG. 10b shows the locus curve of the input impedance of the load modulation circuits in FIGS. 6 and 9 for Rout=50 Ohm;

FIG. 11 a simple characteristic curve of a controllable capacitor (varactor) with the dependence of the capacitance on the control voltage;

FIG. 12 the spectrum with carrier frequency and parasitic sidebands at the modulation frequency;

FIG. 13 a circuit for amplifying an analog useful signal according to a first embodiment of the invention;

FIG. 14 is an example of a detailed implementation of the load modulation circuit 7 from FIG. 13;

FIG. 15 a circuit for amplifying an analog useful signal according to a second embodiment of the invention using the controllable inductance 50;

FIG. 16 a further embodiment of a circuit for amplifying an analog useful signal with an alternative control and load modulation circuit;

FIG. 17 a variant in which the control signals for the controllable capacitors are obtained directly from the baseband signal;

FIG. 18A CV characteristic of a varactor with a typical exponential curve;

FIGS. 19 and 20 Functions c1/c2 and (Cin/Cout)² as a function of the control voltage to check the condition of equation (3).

### DETAILED DESCRIPTION

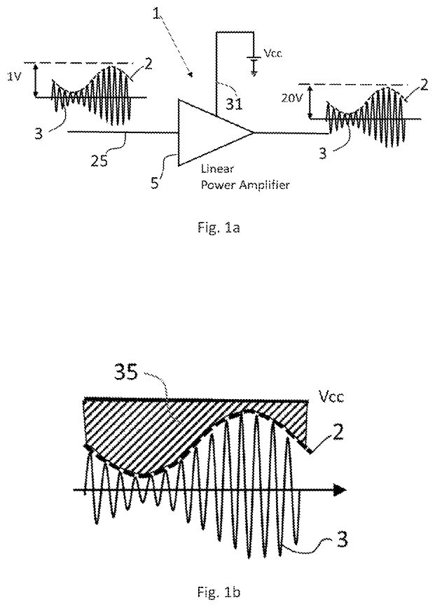

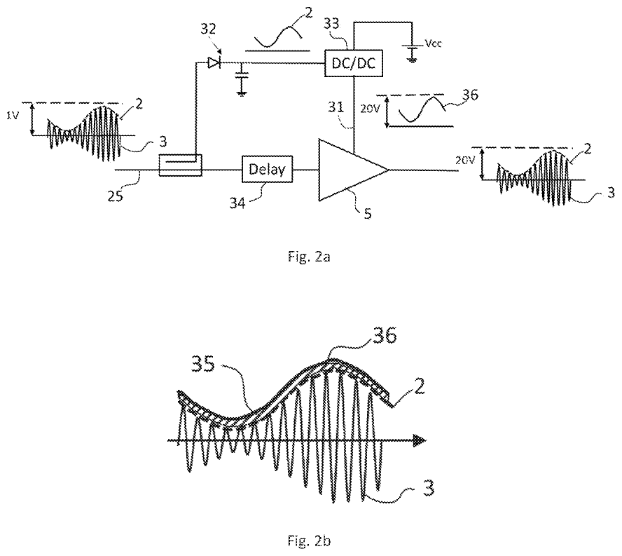

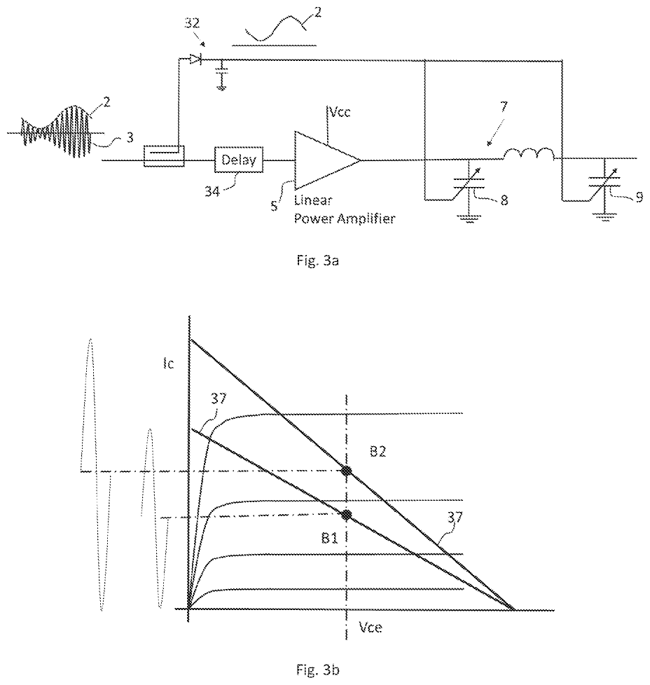

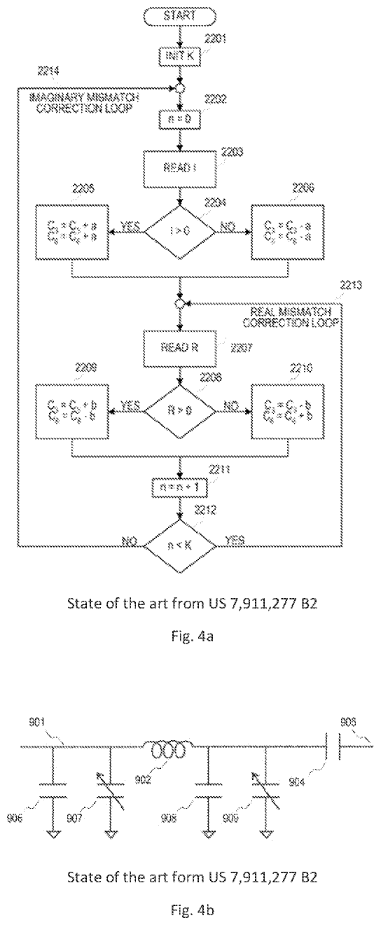

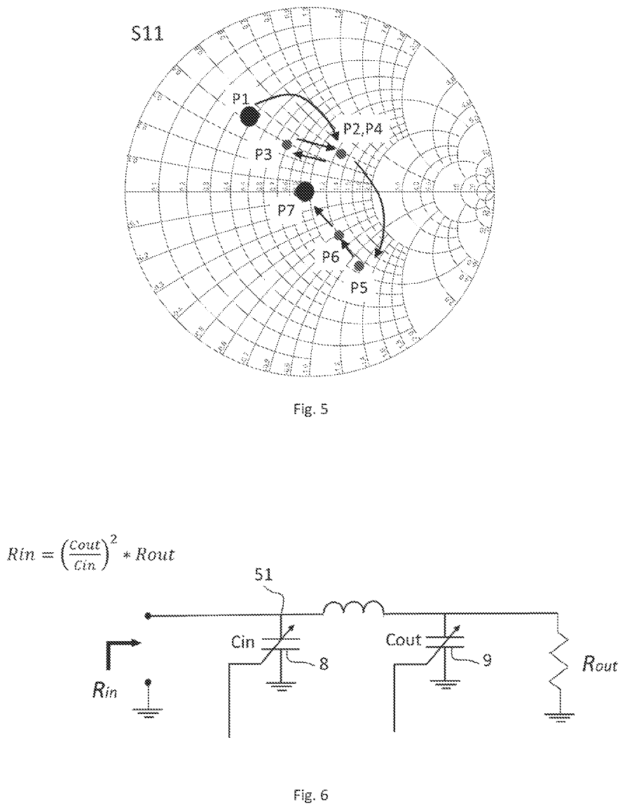

For an explanation of FIGS. 1a, 1b, 2a, 2b, 3a, 3b, 4 and 5, please refer to the introduction to the description.

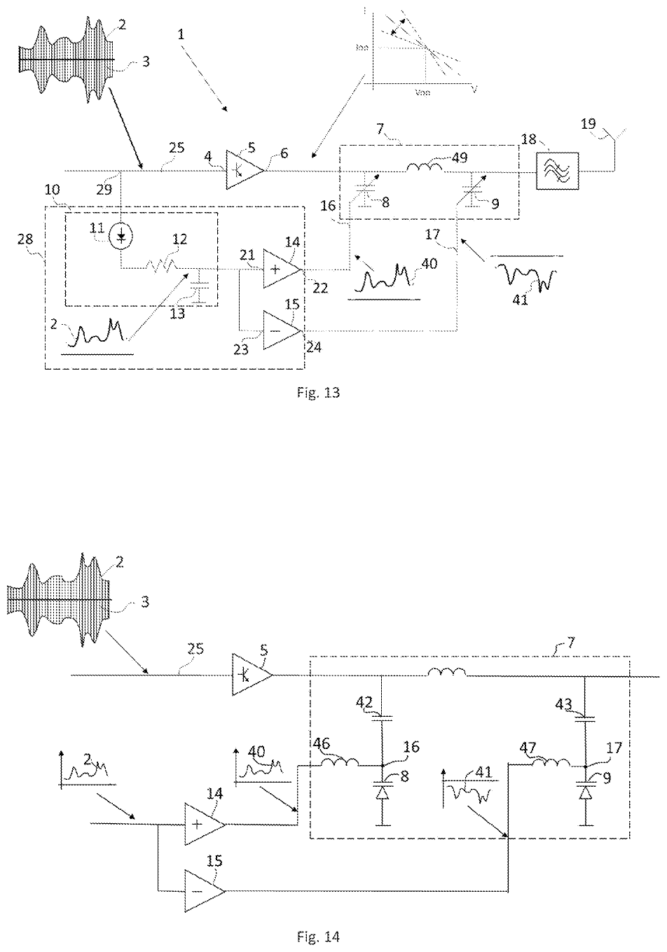

FIG. 13 shows a circuit 1 for amplifying an analog useful signal 2, which operates according to the principle of “load line modulation”. The circuit 1 is essentially used to amplify a useful signal 2, which is routed on a signal transmission path 25 and which may contain audio or video signals, for example, and to transmit it via an antenna 19. In principle, the circuit shown can be integrated in any communication device such as a cell phone, tablet computer or laptop.

The amplifier circuit 1 comprises a power amplifier 5 connected in the signal transmission path 25, to the output 6 of which a load modulation circuit 7 is connected, the impedance of which is controlled as a function of the signal level of the useful signal 2 fed to the input of the circuit 1. The load modulation circuit 7 is followed by a filter 18 and an antenna 19, via which the useful signal 2 is transmitted.

In the embodiment example shown, the load modulation circuit 7 comprises two controlled capacitors 8, 9 (varactors), which are each connected with one of their terminals to the signal transmission path 25 and with their other terminal connected to earth. An inductance 49 is located between the two varactors 8, 9.

To control the two varactors 8, 9, a control circuit 28 is provided, which essentially serves to supply the two varactors 8, 9 with a control signal 40 or an inverted control signal 41 corresponding to the useful signal 2. The input of the control circuit 28 is connected to the signal transmission path 25 via a node 29 and comprises an envelope detector circuit 10, which recovers the useful signal 2 from the amplitude-modulated useful signal 3. For this purpose, the envelope detector circuit 10 comprises a rectifier component with one or more diodes 11 and an RC filter circuit with a resistor 12 and a capacitor 13 connected to earth. A non-inverting operational amplifier 14 and an inverting operational amplifier 15 are connected to the output of the filter circuit 12, 13, which each have an input 21 and 23 respectively and an output 22 and 24 respectively. The inputs of the operational amplifiers 14, 15 are each connected to the signal output of the envelope detector circuit 10 and accordingly receive the useful signal 2 derived from the signal 3.

The non-inverting operational amplifier 14 generates a corresponding, non-inverted control signal 40 at its output and the inverting operational amplifier 15 generates an inverted control signal 41.

The output 22 of the non-inverting operational amplifier 14 is also connected to the terminal 16 of the varactor 8, and the output 24 of the inverting operational amplifier 15 is connected to the terminal 17 of the varactor 9. By controlling the varactors 8, 9 as described above, the impedance of the load modulation circuit changes depending on the signal level of the useful signal 2, whereby the load curve is modulated as shown in FIG. 3b.

Varactors 8, 9, as used in the load modulation circuit 7 of FIG. 13, have a capacitance characteristic, i.e. the capacitance changes with the voltage dropping across the varactor 8, 9. The modulation of the capacitance generates mixed products, which means that modulation by-products f_{carrier}−f_{modulation} or f_{carrier}+f_{modulation} are added to the modulated useful signal 3 carried on the signal transmission path 25 in addition to the actual carrier frequency fc, which interfere with the actual modulated useful signal 3. The proposed circuit for suppressing these unwanted by-products is described in detail below.

FIG. 6 first shows a simple load modulation circuit in pi configuration with two varactors 8 and 9 as shunt elements and an inductor 49 as a series element, as similarly described in U.S. Pat. No. 7,911,277 B2. The resonant frequency of this circuit results in

$$fo = \frac{1}{2 π \sqrt{L * \frac{Cin * Cout}{Cin + Cout}}}$$

The ratio of input impedance to load impedance results in the following for sufficiently high qualities

$$Rin = Rout * {( \frac{Cout}{Cin} )}^{2}$$

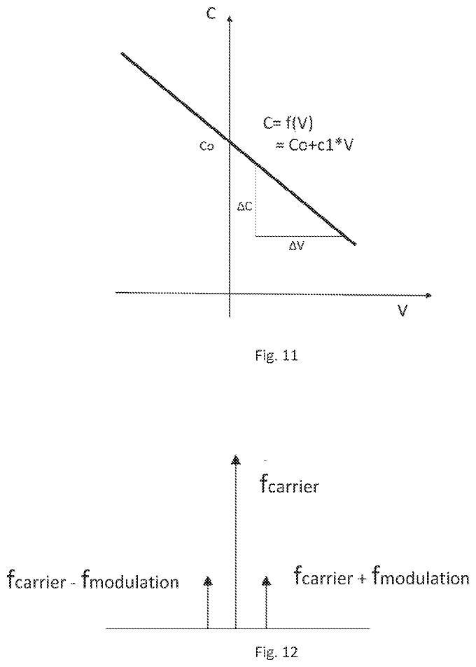

By changing Cin and Cout, the input impedance Rin can be varied with a fixed load resistance Rout. So-called varactors are used for this purpose. FIG. 11 shows the simplest case of a varactor characteristic curve, in which the capacitance depends linearly on the applied voltage and can therefore be described as follows:

$$C = Co + c 1 * U$$

In a simple modulation with a sinusoidal signal of frequency ω1, the capacitance of the varactor results in

$$C = Co + c 1 * Um * sin ( ω 1 * t )$$

If a carrier signal U=Ut*sin(ω2*t) is now applied to the varactor, a current of

$$I ( t ) = sin ( 2 * ω 1 t ) * c 1 * ω 2 * {Um}^{2} + cos ω1t * Co * Um * ω1 + cos ω2t * Co * Um * ω2 + sin ( ω 2 - ω 1 ) t * \frac{1}{2} * c 1 * Um * Ut * ( ω 1 - ω2 ) + sin ( ω 2 + ω 1 ) t * \frac{1}{2} * c 1 * Um * Ut * ( ω 1 + ω 2 )$$

In addition to the actual carrier signal, this results in mixed products such as the unwanted sidebands at a distance of the modulation frequency around the carrier frequency as shown in FIG. 12. If the modulation frequency is small compared to the carrier frequency, which is the case in the usual applications, the interference currents of the generated sidebands can be represented in a simplified form as follows

$$I ( t ) = \frac{1}{2} * ω 2 * c 1 * Um * Ut * ( - sin ( ω 2 - ω 1 ) t + sin ( ω 2 + ω 1 ) t )$$

The interference current generated by the varactor 8 splits at node 51 in FIG. 6 and, with a given adjustment, half of it flows to the input of the circuit, while the other half reaches the load resistor Rout via the load modulation circuit in accordance with the impedance transformation, where it results in

$$I 1 ( t ) = \sqrt{\frac{Rin}{Rout}} * \frac{1}{4} * ω 2 * c 1 * Um * Ut 1 * ( - sin ( ω 2 - ω 1 ) t + sin ( ω 2 + ω 1 ) t )$$

For the interference current I2 generated by varactor 9 with a characteristic slope c2, the following results analogously

$$I 2 ( t ) = \sqrt{\frac{Rout}{Rin}} * \frac{1}{4} * ω 2 * c 2 * Um * Ut 1 * ( - sin ( ω 2 - ω 1 ) t + sin ( ω 2 + ω 1 ) t )$$

For the desired cancellation of the interference currents and frequencies, I1 and I2 must be of the same opposite magnitude so that with identical amplitudes Um of the modulation signals at the two varactors 8 and 9, the ratio of the characteristic slopes c1/c2 of varactors 8 and 9 at the respective operating point is as follows

$$\frac{c 1}{c 2} = \frac{\frac{Δ Cin}{Δ Um}}{\frac{Δ Cout}{Δ Um}} = \frac{Δ Cin}{Δ Cout} = - \frac{Rout}{Rin} = - {( \frac{Cin}{Cout} )}^{2}$$

FIG. 18 shows a typical exponential characteristic curve of a varactor with different slopes of the characteristic curve at different operating points. The effective capacitances Cin, Cout of the varactors 8 and 9 must therefore change in antiphase and in accordance with the impedance ratio (Rout/Rin) in order to avoid generating interfering intermodulation products during the desired load impedance modulation. The ratio of the capacitance changes can be achieved by different operating points of the varactors, by different control signals 40 and 41 or by using varactors with correspondingly different steep characteristic curves or by a combination of all three measures. The resulting amplitude-modulated useful signal 3 is then not or only insignificantly disturbed by the load modulation circuit 7.

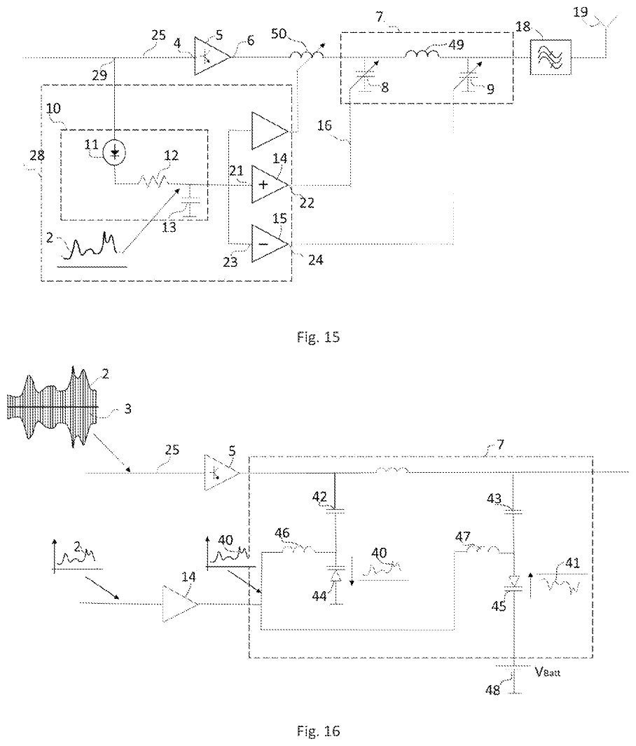

FIG. 15 shows a second embodiment of the invention, in which a controllable inductance 50 is additionally arranged between the amplifier 5 and the load modulation circuit 7 compared to the first embodiment shown in FIG. 13. The advantage of this embodiment is an improved transmission behavior at low load resistances Rout.

As mentioned above, the input impedance of the load modulation circuit 7 becomes purely real if the reactive Pi circuit is only very weakly loaded with the load resistor Rout, i.e. Rout has very high values. However, at low input and output impedances, as is regularly the case with power amplifiers, there is a deviation from the real load.

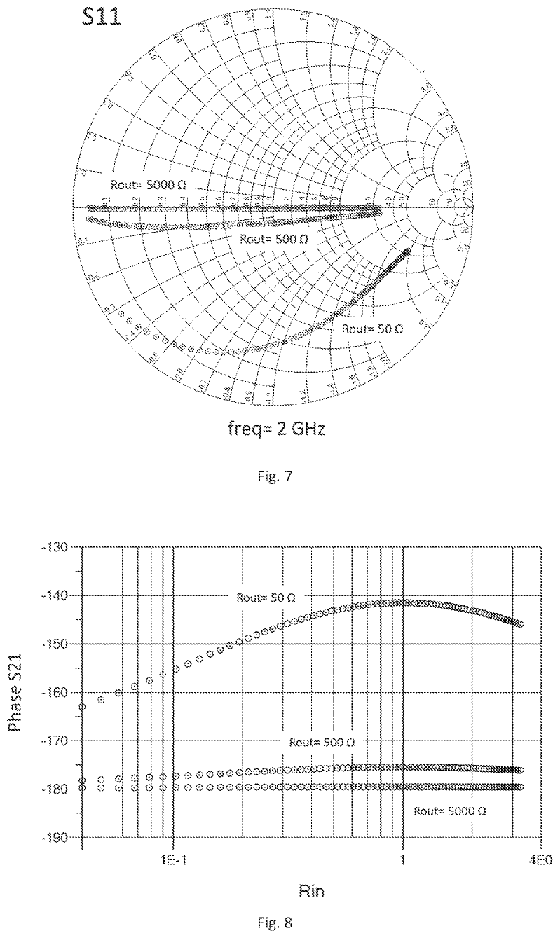

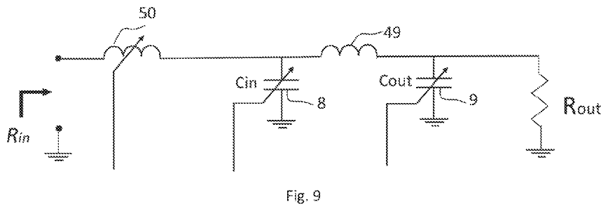

FIG. 7 shows the change in input impedance generated by changing the capacitances Cout and Cin for different output impedances Rout, where a clear deviation from the desired purely real input impedance at low Rout can be seen.

This is accompanied by a variation of the phase response of the transfer function S21, as shown in FIG. 8. For different Rout, Cin and Cout are again varied for load modulation, resulting in undesirable phase responses at low Rout, e.g. 50Ω.

To avoid these phase deviations of the parameters S11 and S21, a controllable inductance 50 is added to the input as shown in FIG. 15. If the inductance is dimensioned as

$$L 50 = L 49 * ( \frac{Cout}{Cin} )$$

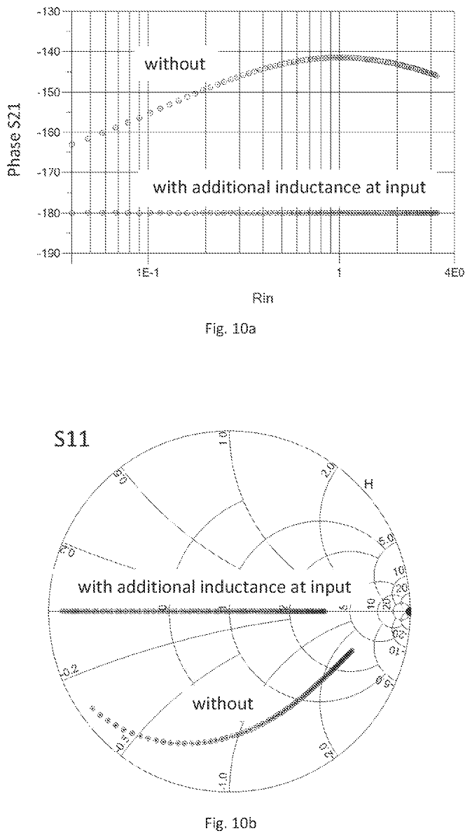

the phase deviations of S11 and S21 are perfectly compensated. FIGS. 10a and 10b compare how S11 and the phase of S21 behave at a rout of 50Ω with and without the additional controllable inductance at the input.

Since controllable inductances are difficult to realize, they are generated in practice by a parallel or series connection of a fixed inductance and a varactor.

The load modulation circuit 7 is followed by a filter 18 and the aforementioned antenna 19, via which the useful signal 2 is finally transmitted.

FIG. 14 shows the detailed implementation of circuit 1 from FIG. 13. Here, the varactors 8 and 9 are connected to the signal transmission path 25 via series capacitors 42 and 43, which allows simpler dimensioning of the circuit. The outputs of the operational amplifiers 14 and 15 are connected to the varactors via chokes 46 and 47 in order to decouple the high-frequency signal at the varactors 8, 9 from the operational amplifiers 14, 15.

FIG. 16 shows a further embodiment of an amplifier circuit 1. Here, the reverse phase of the unwanted mixed products is achieved by reversing the polarity of the second varactor, which simplifies the circuit as a whole. The varactor 45 is connected to a positive supply voltage Vbatt 48 on the cathode side. An increase in the control signal 40 therefore causes an increase in the control voltage at the varactor 44, but a decrease in the control voltage at the varactor 45, which again generates the antiphase.

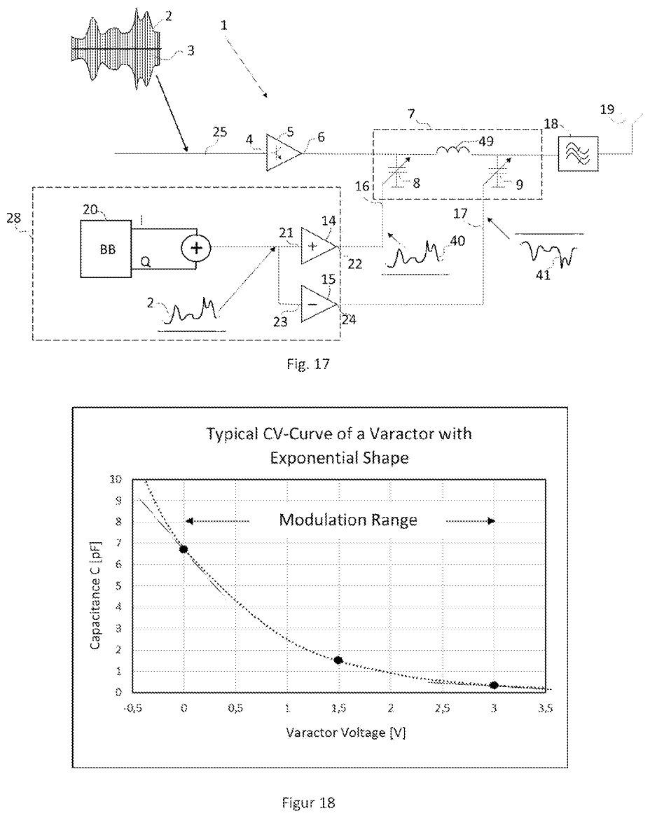

Mobile communication devices such as cell phones or tablet computers usually contain a so-called baseband chip, which generates the useful signal in its natural frequency spectrum—the baseband. The baseband signal or useful signal 2 therefore does not have to be recovered from the modulated useful signal 3, but can be fed directly to the two operational amplifiers 14 and 15 as shown in FIG. 17. The mode of operation and the remaining structure of the circuit 1 in FIG. 17 are identical to the circuit in FIG. 13, so please refer to the description there.

### Example

The following example is intended to show how the conditions specified for interference current cancellation

$$\frac{Rin}{Rout} = {( \frac{Cout}{Cin} )}^{2} \qquad ( 1 )$$

$$\frac{Rin}{Rout} = \frac{c 2}{c 1} \qquad ( 2 )$$

and consequently

$$\frac{c 2}{c 1} = {( \frac{Cout}{Cin} )}^{2} \qquad ( 3 )$$

can be achieved with conventional varactors in the event that both varactors are controlled with the same (but opposite-phase) control signals.

FIG. 18 shows the course of the capacitance over the control voltage (capacitance curve or CV curve) for the assumed example of a standard varactor 8, 9. As can be seen, the varactor characteristic curve has the typical exponential curve. A modulation range of 0-3V was selected for the enveloping modulation voltage Um, i.e. +/−1.5V around an average voltage of 1.5V. The slopes of the characteristic curves at the voltages 0V and 3V are also marked.

The described antiphase control of the two varactors 8, 9 means, starting from the average voltage of 1.5V for one varactor (e.g. 8), an increase in voltage by e.g. 1.5V to 3.0V, while at the same time the voltage at the other varactor (e.g. 9) is reduced from 1.5V to 0V.

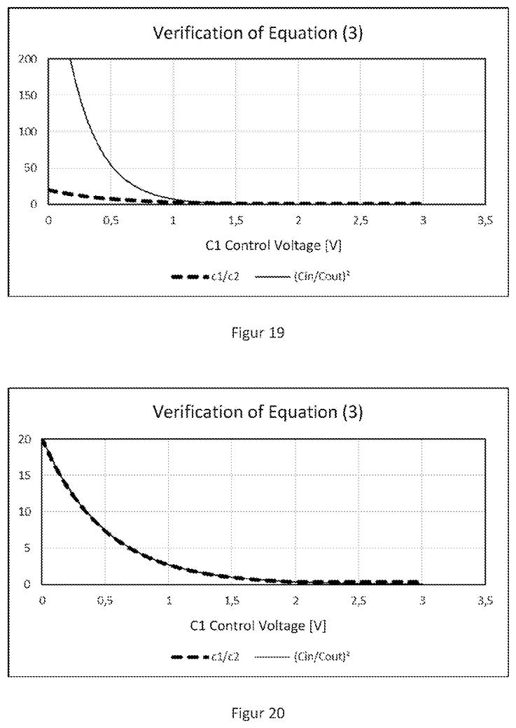

The first step is to check the extent to which equation (3) is fulfilled over the modulation range. To simplify this example, identical varactors 8, 9 are assumed. FIG. 19 shows curves for c1/c2 and (Cin/Cout)² according to equation (3). The deviation of the two curves is clearly visible. This means that interference current cancellation does not occur in the entire output range (between 0 V and 3 V) due to a violation of equation (3).

An adjustment can be made, for example, by changing the capacitance Cin or Cout of one of the controllable capacitors or varactors 8, 9. The simplest case is a shift of one of the two CV curves in the y-direction. This corresponds to the addition of a fixed capacitance to the original exponential CV curve. In reality, varactors available on the market already have such fixed capacitance integrated through parasitic capacitances, e.g. parasitic housing capacitances. Fine adjustment can be achieved by an additional fixed capacitance connected in parallel to the varactor.

FIG. 20 again shows the values for c1/c2 and (Cin/Cout)², now with a fixed capacitance of 1.5 pF inserted in parallel to the varactor. A perfect match and thus interference current cancellation is achieved.

The correct selection of the varactor used and, if necessary, additional wiring with a fixed capacitance can therefore achieve the desired interference current cancellation.

1. A circuit for transmitting and amplifying an analog useful signal in a communication device, comprising:
a signal transmission path via which the useful signal is transmitted in modulated form,
a power amplifier arranged in the signal transmission path having an input and an output, which serves to amplify the useful signal,
a load modulation circuit connected to the output of the power amplifier and having a first and a second controllable capacitor which are both connected to the signal transmission path and are connected to a reference potential, an inductance being arranged in the signal transmission path between the two controllable capacitors; and
a control circuit which controls the two controllable capacitors in antiphase and as a function of the amplitude of the useful signal in such a way that the ratio of the capacitance change of the first controllable capacitor generated by the useful signal to the capacitance change of the second controllable capacitor corresponds to the ratio of the output impedance to the input impedance of the load modulation circuit.

2. The circuit according to claim 1, wherein an additional controllable inductance is connected between the power amplifier and the load modulation circuit, which is driven by the control circuit together with the controllable capacitors, in such a way that the inductance value of the controllable inductance corresponds to the product of the inductance value of the inductance arranged between the two controllable capacitors multiplied by the ratio of the capacitance value of the second capacitor to the capacitance value of the first capacitor.

3. The circuit according to claim 1, wherein the control circuit generates a control signal corresponding to the useful signal and a control signal corresponding to the inverted useful signal, wherein the ratio of the amplitude of the first control signal multiplied by the characteristic slope of the first controllable capacitor and the amplitude of the second control signal multiplied by the characteristic slope of the second controllable capacitor corresponds in terms of magnitude to the ratio of the output impedance to the input impedance of the load modulation circuit.

4. The circuit according to claim 1, wherein the control circuit generates either a control signal corresponding to the useful signal or a control signal corresponding to the inverted useful signal and supplies the relevant control signal to both controllable capacitors, the ratio of the characteristic slopes of the two controllable capacitors corresponds to the ratio of output to input impedance of the load modulation circuit and one of the two controllable capacitors is connected to a negative reference potential or earth, the other to a positive reference potential, so that an increase in the voltage of the control signal results in an increase in the capacitance of one of the capacitors and a decrease in the capacitance of the other.

5. The circuit according to claim 3, wherein the control circuit comprises an inverting operational amplifier and a non-inverting operational amplifier, and an input of the non-inverting operational amplifier and an input of the inverting operational amplifier are connected to the signal transmission path via at least one envelope detector circuit.

6. The circuit according to claim 2, wherein the control circuit generates a control signal corresponding to the useful signal and a control signal corresponding to the inverted useful signal, wherein the ratio of the amplitude of the first control signal multiplied by the characteristic slope of the first controllable capacitor and the amplitude of the second control signal multiplied by the characteristic slope of the second controllable capacitor corresponds in terms of magnitude to the ratio of the output impedance to the input impedance of the load modulation circuit.

7. The circuit according to claim 2, wherein the control circuit generates either a control signal corresponding to the useful signal or a control signal corresponding to the inverted useful signal and supplies the relevant control signal to both controllable capacitors, the ratio of the characteristic slopes of the two controllable capacitors corresponds to the ratio of output to input impedance of the load modulation circuit and one of the two controllable capacitors is connected to a negative reference potential or earth, the other to a positive reference potential, so that an increase in the voltage of the control signal results in an increase in the capacitance of one of the capacitors and a decrease in the capacitance of the other.
